(19) United States
(12) Patent Application Publication
(10) Pub. No.: US 2026/0068779 A1
(43) Pub. Date: Mar. 5, 2026

(54) SEMICONDUCTOR PACKAGE INCLUDING CONDUCTIVE POST

(71) Applicant: SAMSUNG ELECTRONICS CO., LTD., Suwon-si (KR)

(72) Inventors: Hyeyeong Jo, Suwon-si (KR); Seungwoo Park, Suwon-si (KR); Seonghwa Bae, Suwon-si (KR); Seonho Lee, Suwon-si (KR)

(73) Assignee: SAMSUNG ELECTRONICS CO., LTD., Suwon-si (KR)

(21) Appl. No.: 19/220,700

(22) Filed: May 28, 2025

(30) Foreign Application Priority Data
Sep. 5, 2024 (KR) 10-2024-0121129

(51) Int. Cl. H01L 23/498; H01L 23/538; H01L 25/16; H10B 80/00

(52) U.S. Cl. CPC H01L 23/49811; H10B 80/00

(57) ABSTRACT

A semiconductor package includes a first redistribution structure including a plurality of redistribution patterns and a plurality of redistribution insulating layers surrounding the plurality of redistribution patterns; a plurality of conductive posts on the first redistribution structure; and a sealing member on the first redistribution structure and surrounding the plurality of conductive posts, in which the plurality of redistribution insulating layers comprise a first redistribution insulating layer that is closer to the sealing member than other redistribution insulating layers from the plurality of redistribution insulating layers, in which the plurality of redistribution patterns comprise a first redistribution pattern in the first redistribution insulating layer, in which each of the plurality of conductive posts has a nano-twinned copper structure with a (111) orientation.

### CROSS-REFERENCE TO RELATED APPLICATION

This application is based on and claims priority under 35 U.S.C. § 119 to Korean Patent Application No. 10-2024-0121129, filed on Sep. 5, 2024, in the Korean Intellectual Property Office, the disclosure of which is incorporated by reference herein in its entirety.

### BACKGROUND

The embodiments of the present disclosure relate to a semiconductor package, and more particularly, to a semiconductor package including a conductive post.

With the rapid development of the electronics industry and user demand, electronic devices are being miniaturized, multifunctionalized, and increased in capacity. Accordingly, a semiconductor package including a plurality of semiconductor chips is required. A plurality of conductive posts may be provided in an interposer including a plurality of chips mounted on an upper portion of the interposer to achieve electrical connection. Furthermore, a plurality of conductive posts may be provided in a semiconductor package, in which a plurality of chips are stacked, to achieve electrical connection between the plurality of chips and a redistribution structure. Additionally, aspect ratios of a plurality of conductive posts provided in a semiconductor package are being reduced due to the high-integration and miniaturization of the semiconductor package. In the process of forming a sealing member or manufacturing a semiconductor package, the plurality of conductive posts are damaged, such as collapsing or bending, causing the semiconductor package to be defective.

### SUMMARY

The embodiments of the present disclosure provide a semiconductor package that increases manufacturing yield by improving the mechanical properties of a plurality of conductive posts provided therein.

Objectives to be achieved by the embodiments of the present disclosure are not limited to the objectives described above, and other objectives that are not described may be clearly understood by those of ordinary skill in the art from the descriptions below.

According to an aspect of the disclosure, a semiconductor package includes: a first redistribution structure comprising a plurality of redistribution patterns and a plurality of redistribution insulating layers surrounding the plurality of redistribution patterns; a plurality of conductive posts on the first redistribution structure; and a sealing member on the first redistribution structure and surrounding the plurality of conductive posts, wherein the plurality of redistribution insulating layers comprise a first redistribution insulating layer that is closer to the sealing member than other redistribution insulating layers from the plurality of redistribution insulating layers, wherein the plurality of redistribution patterns comprise a first redistribution pattern in the first redistribution insulating layer, wherein an end of each of the plurality of conductive posts is in contact with a part of the first redistribution pattern, and a first seed layer is between each of the plurality of conductive posts and the first redistribution pattern, and wherein each of the plurality of conductive posts has a nano-twinned copper structure with a (111) orientation.

According to an aspect of the disclosure, a semiconductor package includes: a first redistribution structure comprising a plurality of redistribution patterns and a plurality of redistribution insulating layers; a plurality of conductive posts provided on the first redistribution structure; a sealing member provided on the first redistribution structure and surrounding the plurality of conductive posts; and a second redistribution structure on the sealing member, the second redistribution structure electrically connected to the plurality of conductive posts, and comprising a plurality of redistribution patterns and a plurality of redistribution insulating layers, wherein the plurality of redistribution insulating layers of the first redistribution structure comprise a first redistribution insulating layer in contact with the sealing member, and the plurality of redistribution patterns of the first redistribution structure comprise a first redistribution pattern, wherein the first redistribution pattern comprises a first redistribution line pattern and a first redistribution via pattern, wherein the first redistribution line pattern is on the first redistribution insulating layer, the first redistribution via pattern passes through the first redistribution insulating layer, and the first redistribution line pattern and a corresponding first redistribution via pattern are formed integrally, each of the plurality of conductive posts comprises a nano-twinned copper structure with a (111) orientation, a first seed layer is between one end of each of the plurality of conductive posts and the first redistribution pattern, and a second seed layer is provided on one surface of the first redistribution pattern which is an opposite surface of the first seed layer with respect to the first redistribution pattern, and at least one of the first seed layer, the first redistribution pattern, and the second seed layer comprises a nano-twinned copper structure with a (111) orientation.

### BRIEF DESCRIPTION OF DRAWINGS

Embodiments of the present disclosure will be more clearly understood from the following detailed description taken in conjunction with the accompanying drawings in which:

FIG. 1 is a cross-sectional view illustrating a semiconductor package according to one or more embodiments;

FIG. 2 is an enlarged cross-sectional view of a portion A of the semiconductor package illustrated in FIG. 1;

FIG. 3 is an enlarged cross-sectional view schematically illustrating a copper crystal of a part of a conductive post in FIG. 2;

FIG. 4 is an enlarged cross-sectional view of a portion of a semiconductor package according to one or more embodiments, which is similar to the portion A of FIG. 1;

FIG. 5 is an enlarged cross-sectional view of a portion of a semiconductor package according to one or more embodiments, which is similar to the portion A of FIG. 1;

FIG. 6 is an enlarged cross-sectional view of a portion of a semiconductor package according to one or more embodiments, which is similar to the portion A of FIG. 1;

FIG. 7A and FIG. 7B are strain-stress graphs for copper having a nano-twinned structure, ultra fine grain (UFG) copper, and coarse copper;

FIG. 8 is an enlarged cross-sectional view of a portion of a semiconductor package according to one or more embodiments, which is similar to the portion A of FIG. 1;

FIG. 9 is a strain-stress graph according to sizes of copper grains;

FIG. 10 is a cross-sectional view of a semiconductor package according to one or more embodiments; and

FIG. 11 is an enlarged cross-sectional view of a portion C of the semiconductor package of FIG. 10.

### DETAILED DESCRIPTION OF EMBODIMENTS

Hereinafter, embodiments of the present disclosure are described in detail with reference to the attached drawings.

Embodiments are provided to more completely describe the present disclosure to those skilled in the art, following embodiments may be modified into various other forms, and the present disclosure is not limited to the following embodiments. The embodiments are provided to make the present disclosure more faithful and complete and to completely transfer the present disclosure to those skilled in the art. Also, a thickness and size of each layer in the drawings are exaggerated for the sake of convenience and clarity of description.

In the embodiments of the present disclosure, the first direction refers to the X direction, the second direction refers to the Y direction, and the first direction may be perpendicular to the second direction. The third direction is the Z direction, and the third direction may be perpendicular to the first direction and the second direction. A horizontal plane or a plane refers to an X-Y plane. An upper surface of a certain object refers to a surface in a positive third direction with respect to the certain object, and a lower surface of a certain object refers to a surface in a negative third direction with respect to the certain object.

It will be understood that, although the terms first, second, third, fourth, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

A layer may be described as having an upper surface and a lower surface. As understood by one of ordinary skill in the art, the surfaces of a layer may also be described as first and second surfaces, where a first surface may be one of the upper surface and the lower surface of the layer, and the second surface may be the other of the upper surface and the lower surface of the layer.

The specification uses the terms of degree including “substantially” or “about.” In one or more examples, when specifying that a parameter X may be substantially the same as parameter Y, the term “substantially” may be understood as X being within 10% of Y. In one or more examples, when specifying that a parameter is about X, the term “about” may be understood as being within 10% of X.

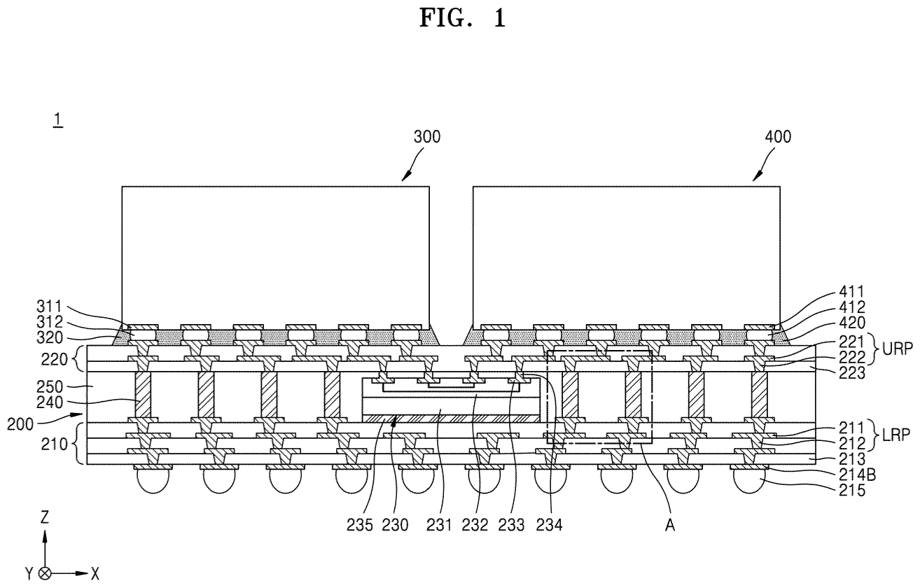

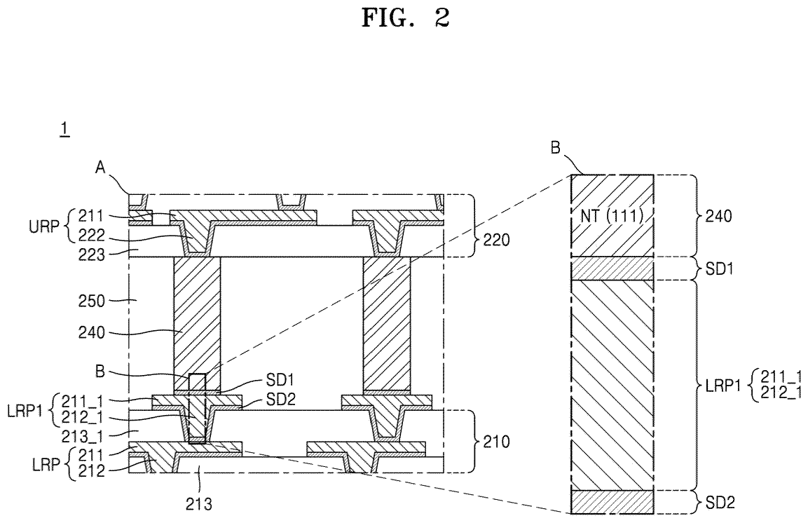

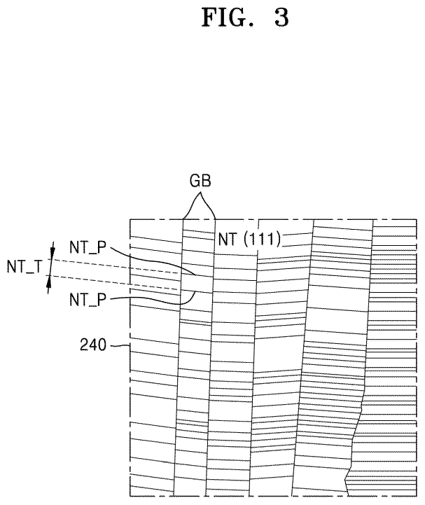

FIG. 1 is a cross-sectional view illustrating a semiconductor package 1 according to one or more embodiments. FIG. 2 is an enlarged cross-sectional view illustrating a portion A of the semiconductor package 1 illustrated in FIG. 1. FIG. 3 is an enlarged cross-sectional view schematically illustrating a copper crystal of a part of a conductive post 240 in FIG. 2.

Referring to FIGS. 1 to 3, the semiconductor package 1 may include an interposer 200, a first upper semiconductor device 300 arranged on an upper surface of the interposer 200, and a second upper semiconductor device 400 arranged on the upper surface of the interposer 200. In one or more embodiments, three or more upper semiconductor chips including the first upper semiconductor device 300 and the second upper semiconductor device 400 may be arranged on the upper surface of the interposer 200. In one or more examples, the interposer 200 is an electrical interface routing between one socket or connection to another. The purpose of the interposer 200 is to spread a connection to a wider pitch or to reroute a connection to a different connection.

The interposer 200 may include a lower redistribution structure 210, an upper redistribution structure 220 provided over the lower redistribution structure 210, a plurality of conductive posts 240 provided between the lower redistribution structure 210 and the upper redistribution structure 220, a first internal semiconductor chip 230 arranged on the upper surface of the lower redistribution structure 210, and a sealing member 250 provided between the lower redistribution structure 210 and the upper redistribution structure 220 and surrounding the first internal semiconductor chip 230. In one or more examples, the redistribution structures 210 and 220 provide a bridge between a semiconductor chip's original layout and another layout for external connections.

The lower redistribution structure 210 may include a plurality of lower redistribution insulating layers 213, and a plurality of lower redistribution patterns LRP provided in the plurality of lower redistribution insulating layers 213. The plurality of lower redistribution patterns LRP may include a plurality of lower redistribution line patterns 211, each being arranged on at least a part of an upper surface or a lower surface of each of the plurality of lower redistribution insulating layers 213, and a plurality of lower redistribution via patterns 212, each passing through each of at least one layer of the plurality of lower redistribution insulating layers 213 and being in contact with a part of each of the plurality of lower redistribution line patterns 211.

The plurality of lower redistribution insulating layers 213 may each be formed of a material film including, for example, an organic compound. In some embodiments, the plurality of lower redistribution insulating layers 213 may each be formed of a material film including an organic polymer material. In some embodiments, the plurality of lower redistribution insulating layers 213 may each be formed of a photosensitive polyimide (PSPI).

The plurality of lower redistribution line patterns 211 and the plurality of lower redistribution via patterns 212 may each include a metal, such as copper (Cu), tungsten (W), titanium (Ti), titanium tungsten (TiW), titanium nitride (TiN), tantalum (Ta), tantalum nitride (TaN), chromium (Cr), aluminum (Al), indium (In), molybdenum (Mo), manganese (Mn), cobalt (Co), tin (Sn), nickel (Ni), magnesium (Mg), rhenium (Re), beryllium (Be), gallium (Ga), or ruthenium (Ru), or an alloy thereof, or a metal nitride but is not limited thereto.

The plurality of lower redistribution line patterns 211 and the plurality of lower redistribution via patterns 212 may each include a seed layer in contact with each of the plurality of lower redistribution insulating layers 213 and a conductive material layer on the seed layer. In some embodiments, the seed layer may be formed by performing physical vapor deposition, and the conductive material layer may be formed by performing plating. One or more of the plurality of lower redistribution line patterns 211 may be formed together with one or more of the plurality of lower redistribution via patterns 212 to form a single unit. For example, each of the plurality of lower redistribution line patterns 211 may be formed together with a part of each of the plurality of lower redistribution via patterns 212, which is in contact with an upper side of each of the plurality of lower redistribution line patterns 211 or a part of each of the plurality of lower redistribution via patterns 212, which is in contact with a lower side of each of the plurality of lower redistribution line patterns 211. The plurality of lower redistribution via patterns 212 may each have a tapered shape of which the horizontal width is elongated to decrease the farther away from the sealing member 250.

The plurality of lower redistribution line patterns 211 may each be arranged between two adjacent layers among the plurality of lower redistribution insulating layers 213 and may each be arranged on an upper surface of an uppermost layer and/or on a lower surface of a lowermost layer of each of the plurality of lower redistribution insulating layers 213.

A plurality of external connection pads 214B may be provided on a lower surface of the lower redistribution structure 210. A plurality of external connection terminals 215 may be respectively arranged on lower surfaces of the plurality of external connection pads 214B. The semiconductor package 1 may be connected to an external electronic device, for example, a printed circuit board through the plurality of external connection terminals 215.

A plurality of conductive posts 240 and a first internal semiconductor chip 230 may be arranged on the lower redistribution structure 210. In one or more examples, a conductive post is an electrical connection between two different redistribution structures. The conductive post may have a first surface contacting a first redistribution structure and a second surface contacting a second redistribution structure. The plurality of conductive posts 240 may be arranged on the lower redistribution structure 210 to be separated from the first internal semiconductor chip 230. The plurality of conductive posts 240 may each include, for example, a metal, such as copper (Cu), tungsten (W), titanium (Ti), titanium tungsten (TiW), titanium nitride (TiN), tantalum (Ta), tantalum nitride (TaN), chromium (Cr), aluminum (Al), indium (In), molybdenum (Mo), manganese (Mn), cobalt (Co), tin (Sn), nickel (Ni), magnesium (Mg), rhenium (Re), beryllium (Be), gallium (Ga), or ruthenium (Ru), or an alloy thereof, or a metal nitride but is not limited thereto.

The plurality of conductive posts 240 may each be on a part of each of the plurality of lower redistribution line patterns 211. The plurality of lower redistribution line patterns 211 provided on an upper surface of the lower redistribution structure 210 may be referred to as a plurality of internal connection pads. The plurality of conductive posts 240 may be respectively arranged on the plurality of internal connection pads. The first internal semiconductor chip 230 may not be arranged on the plurality of internal connection pads. In some embodiments, a passive component may be between the upper redistribution structure 220 and the lower redistribution structure 210 to be laterally separated from the first internal semiconductor chip 230. For example, a passive component may be the same shape as one of the conductive posts without conductive material. An aspect ratio (A/R) of each of the plurality of conductive posts 240 may be 1 to 30. However, due to miniaturization of the semiconductor package 1, the aspect ratio of each of the plurality of conductive posts 240 may increase to a range of, for example, 3 to 30.

The first internal semiconductor chip 230 may be attached onto the lower redistribution structure 210 by, for example, a die attach film 235. In some embodiments, the first internal semiconductor chip 230 may be attached onto upper surfaces of uppermost layers of one or more of the plurality of lower redistribution insulating layers 213 included in the lower redistribution structure 210.

The first internal semiconductor chip 230 may include a first internal substrate 231, a plurality of connection wiring patterns 232, and internal chip pads 233. The first internal substrate 231 may be a semiconductor substrate. For example, the first internal substrate 231 may include silicon (Si).

The plurality of connection wiring patterns 232 may be formed on the first internal substrate 231 through a general semiconductor device wiring process. The plurality of connection wiring patterns 232 may be connection line wires formed in one layer, but the embodiments of the present disclosure are not limited to these configurations. In some embodiments, the plurality of connection wiring patterns 232 may include connection line wires formed in two or more layers, and via plugs connecting the connection line wires formed in different layers to each other, and an inter-wiring insulating layer may be formed between the connection line wires and the via plugs. The first internal semiconductor chip 230 may be formed by performing only a wiring process without forming individual electronic components on the first internal substrate 231. The first internal semiconductor chip 230 may be referred to as an internal interposer chip herein.

The upper redistribution structure 220 may be on the plurality of conductive posts 240 and the first internal semiconductor chip 230. The upper redistribution structure 220 may include one or more upper redistribution insulating layers 223, and a plurality of upper redistribution patterns URPs provided in the upper redistribution insulating layers 223. The plurality of upper redistribution patterns URP may respectively include a plurality of upper redistribution line patterns 221, and a plurality of upper redistribution via patterns 222 respectively passing through the plurality of upper redistribution insulating layers 223 and each being in contact with a part of each of the plurality of upper redistribution line patterns 221.

In one or more examples, the upper redistribution line patterns 221, the plurality of upper redistribution via patterns 222, and the plurality of upper redistribution insulating layers 223 may be the same size, shape, and/or material as the plurality of lower redistribution line patterns 211, the plurality of lower redistribution via patterns 212, and the plurality of lower redistribution insulating layers 213, and accordingly, detailed descriptions thereof are omitted. However, as understood by one of ordinary skill in the art, the upper redistribution line patterns 221, the plurality of upper redistribution via patterns 222, and the plurality of upper redistribution insulating layers 223 may differ in size, shape, or material as the plurality of lower redistribution line patterns 211, the plurality of lower redistribution via patterns 212, and the plurality of lower redistribution insulating layers 213.

The number of upper redistribution insulating layers 223 of the upper redistribution structure 220 may be equal to or less than the number of lower redistribution insulating layers 213 of the lower redistribution structure 210. For example, the lower redistribution structure 210 may have at least three lower redistribution insulating layers 213, and the upper redistribution structure 220 may have two upper redistribution insulating layers 223 which are less than the number of lower redistribution insulating layers 213 of the lower redistribution structure 210. However, the embodiments of the present disclosure not limited to the number of upper redistribution insulating layers 223 provided in the upper redistribution structure 220 and the number of lower redistribution insulating layers 213 provided in the lower redistribution structure 210.

In one or more examples, the plurality of conductive posts 240 may respectively electrically connect the plurality of upper redistribution patterns URP of the upper redistribution structure 220 to the plurality of lower redistribution patterns LRP of the lower redistribution structure 210. For example, the plurality of conductive posts 240 may be respectively provided on the internal connection pads arranged on an uppermost surface of the lower redistribution structure 210 among the plurality of upper redistribution line patterns 221.

A plurality of connection pillars 234 may connect the first internal semiconductor chip 230 to the plurality of upper redistribution patterns URP of the upper redistribution structure 220. The plurality of connection pillars 234 may extend vertically on the internal chip pad 233 to be electrically connected to the plurality of upper redistribution patterns URP, respectively.

The plurality of connection pillars 234, the plurality of conductive posts 240, and the sealing member 250 surrounding the first internal semiconductor chip 230 may be provided between the lower redistribution structure 210 and the upper redistribution structure 220. The sealing member 250 may be formed of epoxy molding compound (EMC) or a polymer material.

A side surface of the lower redistribution structure 210, a side surface of the sealing member 250, and a side surface of the upper redistribution structure 220 may be aligned with each other in a vertical direction. Chemical-mechanical polishing (CMP) is performed at once for upper surfaces of the plurality of conductive posts 240, upper surfaces of the plurality of connection pillars 234, and an upper surface of the sealing member 250 provided on the upper redistribution structure 220, and accordingly, the upper surfaces of the plurality of conductive posts 240, the upper surfaces of the plurality of connection pillars 234, and the upper surface of the sealing member 250 may be coplanar with one another.

The first upper semiconductor device 300 may be provided on the upper redistribution structure 220. According to one or more embodiments, the second upper semiconductor device 400, laterally separated from the first upper semiconductor device 300, may be provided on the upper redistribution structure 220.

The first upper semiconductor device 300 may include, for example, a central processing unit (CPU) chip, a graphics processing unit (GPU) chip, or an application processor (AP) chip. The second upper semiconductor device 400 may include, for example, a dynamic random access memory (DRAM) chip, a static random access memory (SRAM) chip, a flash memory chip, an electrically erasable and programmable read-only memory (EEPROM) chip, a phase-change random access memory (PRAM) chip, a magnetic random access memory (MRAM) chip, or a resistive random access memory (RRAM) chip.

The second upper semiconductor device 400 may be a semiconductor device in which a plurality of semiconductor chips are stacked vertically. The plurality of semiconductor chips may be stacked semiconductor chips including through silicon vias (TSVs). For example, the second upper semiconductor device 400 may be a high bandwidth memory (HBM) device.

A plurality of first chip pads 311 may be provided on a lower surface of the first upper semiconductor device 300. Similarly to the first upper semiconductor device 300, a plurality of second chip pads 411 may be provided on a lower surface of the second upper semiconductor device 400.

The plurality of first chip pads 311 of the first upper semiconductor device 300 may be electrically connected to a plurality of upper connection pads provided on the upper redistribution structure 220 through a plurality of first chip connection members 312. Similarly, the plurality of second chip pads 411 of the second upper semiconductor device 400 may be electrically connected to a plurality of upper connection pads provided on the upper redistribution structure 220 through a plurality of second chip connection members 412.

The plurality of upper connection pads may be respectively electrically connected to the plurality of upper redistribution line patterns 221 and the plurality of upper redistribution via pattern 222 of the upper redistribution structure 220. The plurality of first chip connection members 312 and the plurality of second chip connection members 412 may be, for example, bumps, solder balls, or conductive pillars.

The first upper semiconductor device 300 may include, for example, a semiconductor substrate. The semiconductor substrate may include silicon (Si). In one or more examples, the semiconductor substrate may include a semiconductor element, such as germanium (Ge, or a compound semiconductor, such as silicon carbide (SiC), gallium arsenide (GaAs), indium arsenide (InAs), or indium phosphide (InP). The semiconductor substrate may have an active surface and an inactive surface opposite to the active surface. In some embodiments, the active surface of the semiconductor substrate may face the upper redistribution structure 220. A semiconductor device including a plurality of individual devices of various types may be formed on the active surface of the semiconductor substrate. The second upper semiconductor device 400 may also include a semiconductor substrate, and detailed descriptions thereof may be substantially the same as descriptions of the semiconductor substrate provided in the first upper semiconductor device 300.

A first under-fill layer 320 surrounding the plurality of first chip connection members 312 may be provided between the first upper semiconductor device 300 and the upper redistribution structure 220. The first under-fill layer 320 may be formed by, for example, a capillary under-fill method, and the first under-fill layer 320 may be formed of an epoxy resin. Similarly, a second under-fill layer 420 surrounding the second chip connection member 412 may be provided between the second upper semiconductor device 400 and the upper redistribution structure 220.

The semiconductor package 1 may be, for example, a fan-out package (e.g., package with connections fanned-out of a chip surface). As illustrated in FIG. 1, footprints occupied by the first upper semiconductor device 300 and the second upper semiconductor device 400 may be less than horizontal areas of the upper redistribution structure 220 and the lower redistribution structure 210. The footprints occupied by the first upper semiconductor device 300 and the second upper semiconductor device 400 may vertically overlap both the upper redistribution structure 220 and/or the lower redistribution structure 210. A part of an upper redistribution pattern of the upper redistribution structure 220 and a part of a lower redistribution pattern of the lower redistribution structure 210 may extend to protrude more horizontally and outwardly from the footprints occupied together by the first upper semiconductor device 300 and the second upper semiconductor device 400.

Referring again to FIG. 2, the plurality of lower redistribution insulating layers 213 may include a first lower redistribution insulating layer 2131. The first lower redistribution insulating layer 2131 is the closest layer to the sealing member 250 among the plurality of lower redistribution insulating layers 213, and at least a part of an upper surface of the first lower redistribution insulating layer 213_1 may be in contact with a lower surface of the sealing member 250.

The plurality of lower redistribution patterns LRP may each include a first lower redistribution pattern LRP1. The first lower redistribution pattern LRP1 may be provided in a first lower redistribution insulating layer 213_1. The first lower redistribution pattern LRP1 may include a first lower redistribution line pattern 211_1 and a first lower redistribution via pattern 212_1. The first lower redistribution via pattern 2121 may pass through the first lower redistribution insulating layer 213_1. The first lower redistribution line pattern 2111 may be on the first lower redistribution insulating layer 213_1. The first lower redistribution line pattern 211_1 and the first lower redistribution via pattern 212_1 corresponding to the first lower redistribution line pattern 211_1 may be provided as a single unit.

A first seed layer SD1 may be provided between the first lower redistribution line pattern 211_1 and the conductive post 240 corresponding to the first lower redistribution line pattern 211_1. The conductive post 240 may be on the first seed layer SD1. The first seed layer SD1 may be a base for performing electroplating to form the conductive post 240. For example, the SD1 may be a thin layer deposited on the first lower redistribution line patter 211_1 to provide nucleation sites for nanowires to grow on.

A second seed layer SD2 may be provided along a lower surface of the first lower redistribution pattern LRP1. The second seed layer SD2 may be provided between the first lower redistribution pattern LRP1 and the first lower redistribution insulating layer 213_1, and between the first lower redistribution pattern LRP1 and the lower redistribution pattern LRP under the first lower redistribution pattern LRP1. The second seed layer SD2 may be a base for performing plating to form the first lower redistribution pattern LRP1. The second seed layer SD2 may be formed in the same manner as discussed above for the first seed layer SD1.

FIG. 2 illustrates a portion A of the semiconductor package 1 on the left, and illustrates a portion B, on the right, which includes the conductive post 240, the first seed layer SD1, the first lower redistribution pattern LRP1, and the second seed layer SD2, and is an enlarged portion of the portion A. The conductive post 240 may be formed of copper having a nano twinned (NT) structure with a (111) orientation. As understood by one of ordinary skill in the art, the 111 orientation is the plane the face of a crystal such as 1 unit on an a-axis, 1 unit on a b-axis, and 1 unit on a c-axis.

In one or more examples, the NT structure indicates two crystals formed with the same material and having symmetry with respect to a crystal plane. A plane or axis between two crystals having symmetry may be called a twin plane or twin axis. In a face-centered cubic (FCC) crystal structure including copper, an interface may be formed with a (111) mirror plane in which a stacking order of the general (111) plane is reversed. Twins may grow in a stacking manner in which a thickness of the twins extends along the (111) crystal plane to form a twin structure. The twin structure may have a boundary defined by a coherent twin boundary (CTB), which is a high-angle grain boundary. In relation to the thickness of the twins, an interval between nano twin planes NT_P illustrated in FIG. 3 may be referred to as a nano twin thickness NT_T. Grain boundaries GB may be observed in a nano twin structure. The nano twin planes NT_P may be formed in a generally consistent direction, and the grain boundaries GB may also be formed in a generally consistent direction. For example, the nano twin planes NT_P may extend substantially parallel to an X-Y plane, and the grain boundaries GB may extend substantially parallel to a Z axis.

In one or more examples, the (111) orientation indicates an orientation of crystal refers to a Miller index indicating a certain plane of a copper (Cu) crystal. The Miller index is a method of designating an orientation of a crystal plane in crystallography and may be expressed in the format of hkl. Here, h, k, and 1 may each be an integer indicating a position where the crystal plane meets the crystal axis.

Nano-twinned copper may be formed through various methods. For example, copper having a nano-twinned structure with a (111) orientation, which forms the conductive post 240, may be formed through electroplating, which is a process that may use an electric current to deposit a thin layer of metal onto a solid surface. For example, formation of the copper having a nano-twinned structure with a (111) orientation through electroplating may be achieved adjusting the type of copper salt, the electric density applied during a plating process, and so on.

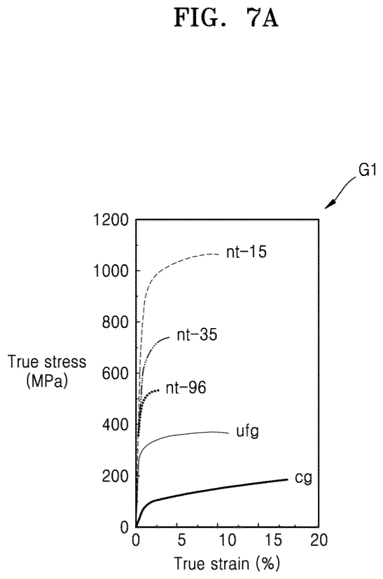

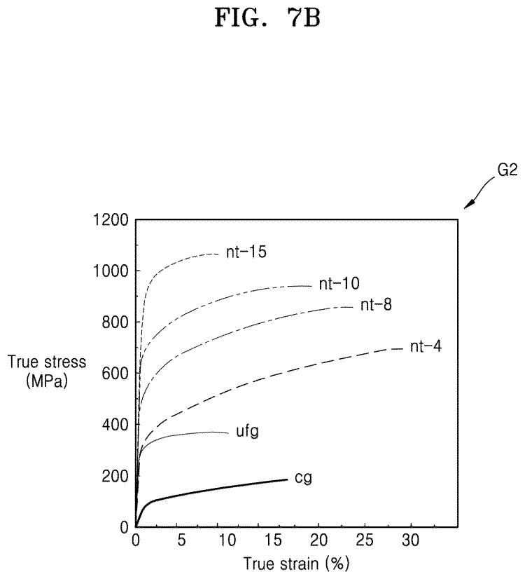

Referring first to FIG. 7A and FIG. 7B, FIG. 7A and FIG. 7B respectively show a first graph G1 for a strain-stress relationship of an average nano-twinned thickness of nano-twinned copper, and a second graph G2 for a strain-stress relationship of ultra fine grain (UFG) copper and coarse grain copper.

As shown in the first graph G1 of FIG. 7A and the second graph G2 of FIG. 7B, for example, coarse grain copper has a strain exceeding 15% when a stress close to 200 MPa is applied. As shown in the first graph G1, nano-twinned copper shows higher mechanical properties than coarse grain copper and UFG copper. For example, FIG. 7A illustrates that when an average nano-twinned thickness is 96 nm, the mechanical properties are sequentially better than when the average nano-twinned thicknesses are 35 nm and 15 nm. Similarly, FIG. 7B illustrates that when the average nano-twinned thicknesses are 8 nm, 10 nm, and 15 nm, the mechanical properties are sequentially better than when the average nano-twinned thickness is 4 nm. Although the mechanical properties change depending on the average nano-twinned thicknesses, the embodiments of the present disclosure show that the mechanical properties of the nano-twinned copper are better than the mechanical properties of the UFG copper or the coarse-grain copper.

Grain and orientation of the copper particles of the conductive post 240 may be confirmed through electron backscatter diffraction (EBSD). For example, the average nano-twinned thickness of the nano-twinned copper of the conductive post 240 may be about 5 nm to about 35 nm. In one or more examples, the average nano-twinned thickness of the nano-twinned copper of the conductive post 240 may be about 8 nm to about 96 nm. For example, a content of nano-twinned copper with a (111) orientation included in the conductive post 240 may be about 90% to about 99.9%.

The other contents excluding the content of nano-twinned copper with a (111) orientation included in the conductive post 240 may include non-twinned copper grains, copper grains with an orientation of, for example, (100), (110), or so on, amorphous regions, defective regions, or so on.

A first upper redistribution insulating layer may be included in the plurality of upper redistribution insulating layers 223. The first upper redistribution insulating layer may refer to one of the plurality of upper redistribution insulating layers 223 which is in direct contact with the sealing member 250. In a process of manufacturing the se,miconductor package 1, the sealing member 250 may be formed on the lower redistribution structure 210 to surround the plurality of conductive posts 240. Thereafter, a part of the sealing member 250 and a part of each of the plurality of conductive posts 240 may be removed through chemical and mechanical polishing. Thereafter, the first upper redistribution insulating layer is formed on an upper surface of the sealing member 250, and the plurality of upper redistribution patterns URP may be formed. In one or more examples, because the sealing member 250 is formed to surround the plurality of conductive posts 240, the plurality of upper redistribution patterns URP included in the upper redistribution structure 220, and a seed layer that serves as a base for forming the plurality of upper redistribution patterns URP do not need to be formed of copper having a nano-twinned structure with a (111) orientation.

For example, the plurality of upper redistribution patterns URP and the seed layer that serves as a base for forming the plurality of upper redistribution patterns URP may all be formed of non-twinned copper. In one or more examples, the plurality of upper redistribution patterns URP may have a content of nano-twinned copper that is less than 10%.

In a typical semiconductor package manufacturing process, a plurality of conductive posts may be formed on a lower redistribution structure, and then a sealing member may be formed on the lower redistribution structure to surround the plurality of conductive posts. In this process, as an aspect ratio of each of the plurality of conductive posts increases with miniaturization and densification of the semiconductor package, some of the plurality of conductive posts may be damaged during a process of forming the sealing member or other processes.

In the semiconductor package 1 according to the embodiments of the present disclosure, the plurality of conductive posts 240 may each be formed of copper of a (111) orientation with superior mechanical properties, and accordingly, the possibility of damage to the plurality of conductive posts 240 during a process of manufacturing the semiconductor package 1 may be reduced due to the superior mechanical properties. Therefore, the possibility of defects occurring during the process of manufacturing the semiconductor package 1 is reduced, and a manufacturing yield of the semiconductor package 1 may be increased.

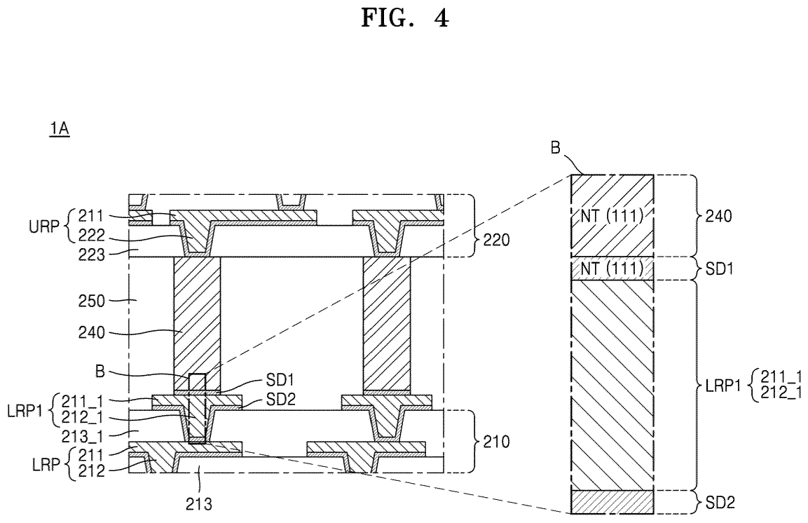

FIG. 4 is an enlarged cross-sectional view of a portion of a semiconductor package 1A according to one or more embodiments, which is similar to the portion A of FIG. 1. Descriptions not made separately may be substantially the same as the descriptions made above.

Referring to FIG. 4, a first seed layer SD1 may be provided between a first lower redistribution line pattern 211_1 and a conductive post 240 corresponding to the first lower redistribution line pattern 211_1. The conductive post 240 may be arranged on the first seed layer SD1. A second seed layer SD2 may be provided along a lower surface of the first lower redistribution pattern LRPL. The second seed layer SD2 may be provided between a first lower redistribution pattern LRP1 and a first lower redistribution insulation layer 213_1, and between the first lower redistribution pattern LRP1 and a lower redistribution pattern LRP under the first lower redistribution pattern LRPL.

FIG. 4 illustrates an enlarged view of a region B, on the right, which is a portion including the conductive post 240, the first seed layer SD1, the first lower redistribution pattern LRP1, and the second seed layer SD2. As illustrated in FIG. 4, the conductive post 240 and the first seed layer SD1 may be formed of copper having a nano-twinned structure with a (111) orientation.

As described above with reference to FIG. 2, the conductive post 240 may be formed of copper having a nano-twinned structure with a (111) orientation, which is formed through electroplating. In addition, the first seed layer SD1 may be formed of copper having a nano-twinned structure with a (111) orientation, which is formed by physical vapor deposition (PVD). The first seed layer SD1 may be formed of copper having the nano-twinned structure with a (111) orientation through a physical vapor deposition by properly adjusting adjustable factors of the physical vapor deposition which includes, for example, setting of pressure of an inert gas used in the physical vapor deposition, thicknesses of copper particles formed per time, and temperature.

By forming the first seed layer SD1 and the conductive post 240 provided on the first seed layer SD1 with copper having a nano-twinned structure with a (111) orientation, the conductive post 240 having better mechanical properties may be formed.

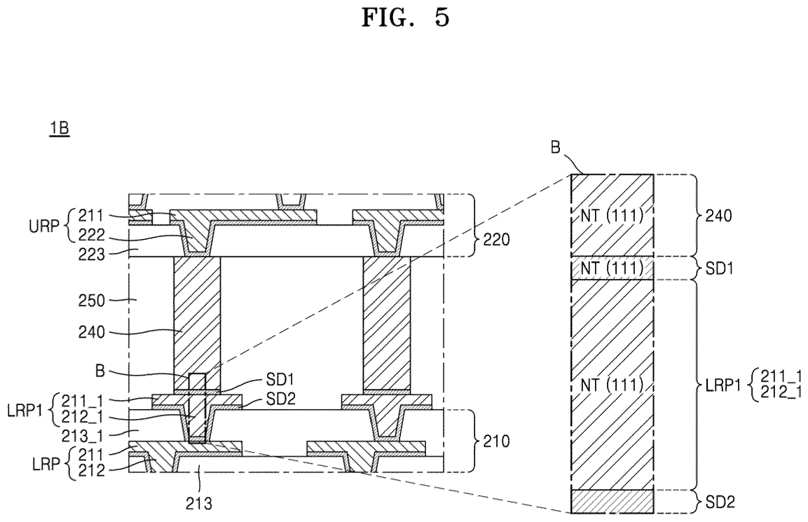

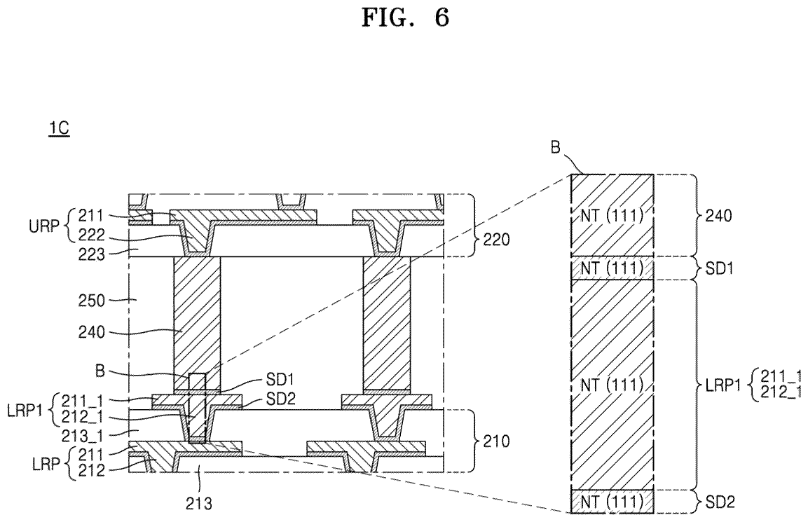

FIG. 5 is an enlarged cross-sectional view of a portion of a semiconductor package 1B according to one or more embodiments, which is similar to the portion A of FIG. 1. FIG. 6 is an enlarged cross-sectional view of a portion of a semiconductor package 1C according to one or more embodiments, which is similar to the portion A of FIG. 1. Descriptions not made separately may be substantially the same as the descriptions made above.

FIG. 5 illustrates an enlarged view of a region B, on the right, which is a portion including a conductive post 240, a first seed layer SD1, a first lower redistribution pattern LRP1, and a second seed layer SD2. The conductive post 240, the first seed layer SD1, and the first lower redistribution pattern LRP1 may be formed of copper having a nano-twinned structure with a (111) orientation.

The first lower redistribution pattern LRP1 may be formed by electroplating in the same manner as the conductive post 240. A plurality of openings may be formed in the first lower redistribution insulating layer 213_1, and the second seed layer SD2 may be formed to extend on the plurality of openings and the first lower redistribution insulating layer 213_1. Thereafter, the first lower redistribution pattern LRP1 may be formed on the second seed layer SD2 by using the second seed layer SD2 as a base.

Referring to FIG. 6, the second seed layer SD2 may be formed of copper having a nano-twinned structure with a (111) orientation, which is formed by PVD. That is, the first seed layer SD1 and the second seed layer SD2 may be formed of copper having a nano-twinned structure with a (111) orientation, which is formed by PVD, and the conductive post 240 and the first lower redistribution pattern LPR1 may be formed of copper having a nano-twinned structure with the (111) orientation, which is formed by electroplating.

FIG. 7A and FIG. 7B respectively illustrate the first graph G1 and the second graph G2 which are strain-stress graphs on copper having a nano-twinned structure, UFG copper, and rough copper. Descriptions not made separately may be substantially the same as the descriptions made above.

Referring to FIGS. 7A and 7B, the first graph G1 of FIG. 7A and the second graph G2 of FIG. 7B show results of comparison of copper having an average nano-twinned thickness of 15 nm to 96 nm and UFG copper and coarse grain copper, in a case where a strain rate is 6×10⁻¹s⁻¹. As described above, it may be seen that the copper having a nano-twinned structure has better mechanical properties than the UFG copper and coarse-grain copper.

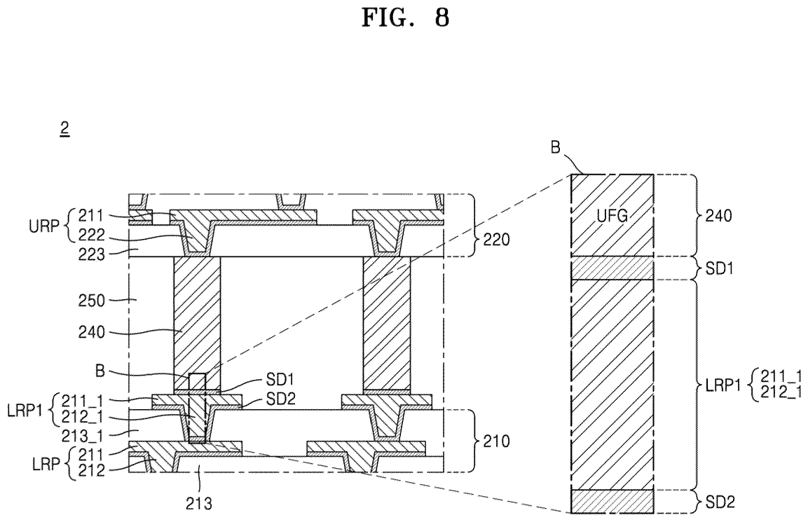

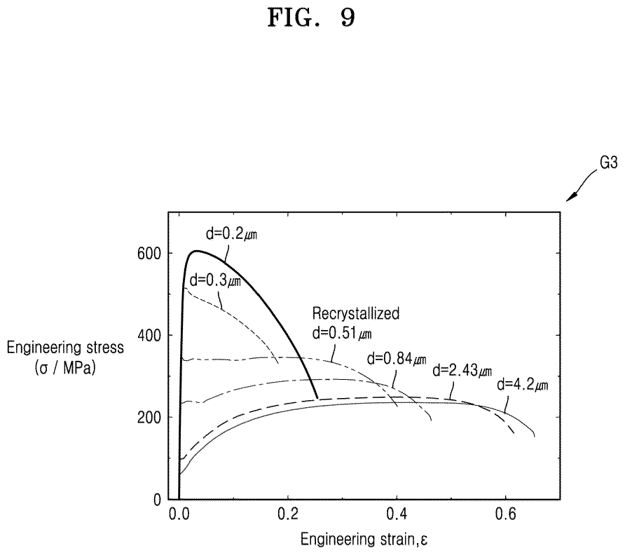

FIG. 8 is an enlarged cross-sectional view of a portion of a semiconductor package 2 according to one or more embodiments, which is similar to the portion A of FIG. 1. FIG. 9 is a strain-stress graph G3 according to sizes of copper grains. Descriptions not made separately may be substantially the same as the descriptions made above.

Referring to FIG. 8 and FIG. 9, a conductive post 240 may be formed of UFG copper. As illustrated in FIG. 7A and FIG. 7B, UFG copper has better mechanical properties than the coarse grain copper. The third graph G3 of FIG. 9 is a strain-stress graph according to different grain sizes of a copper inspection object. It may be seen that, in the third graph G3, the strain according to stress is generally reduced as the size of a copper grain is reduced. Therefore, it may be seen that the mechanical properties of a material to be applied to the semiconductor package 2 are generally increased as the size of a copper grain is reduced.

For example, an average size of copper particles of the conductive post 240 provided in the semiconductor package 2 may be about 0.1 μm to about 0.8 μm. In addition, one or more of the first seed layer SD1, the first lower redistribution pattern LPR1, and the second seed layer SD2 may be formed of UFG copper in the same manner as the conductive post 240. For example, the conductive post 240, the first seed layer SD1, the first lower redistribution pattern LPR1, and the second seed layer SD2 may all be formed of UFG copper.

In the semiconductor package 2 according to one or more embodiments, a plurality of conductive posts 240 are formed of UFG copper with better mechanical properties than coarse grain copper, and thus, a possibility that the plurality of conductive posts 240 are damaged during a process of manufacturing the semiconductor package 2 may be reduced due to superior mechanical properties of the semiconductor package 2. Because a possibility that a defect occurs during the process of manufacturing the semiconductor package 2 is reduced, a manufacturing yield of the semiconductor package 2 may be increased.

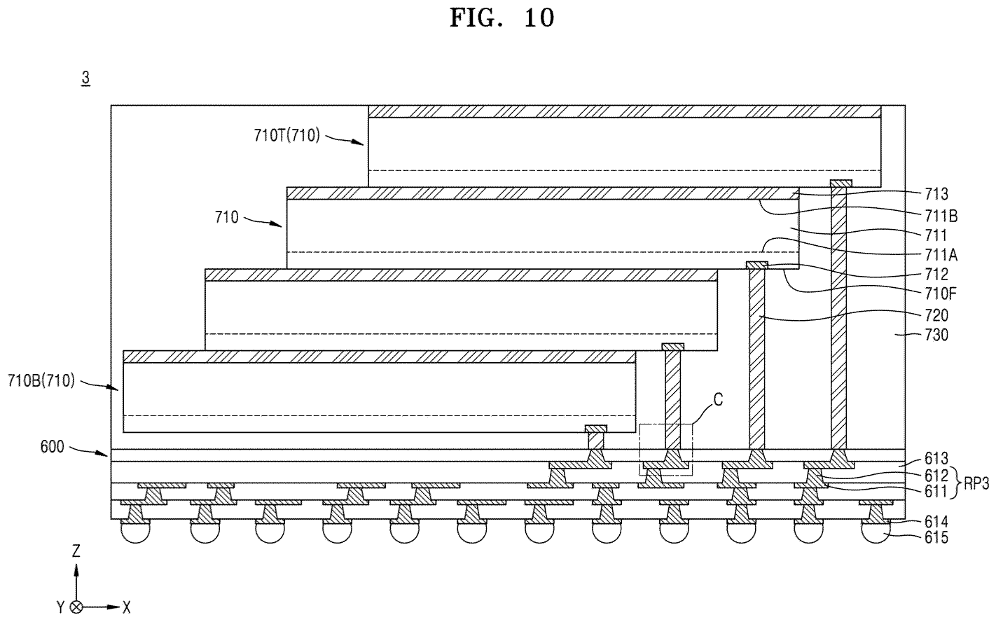

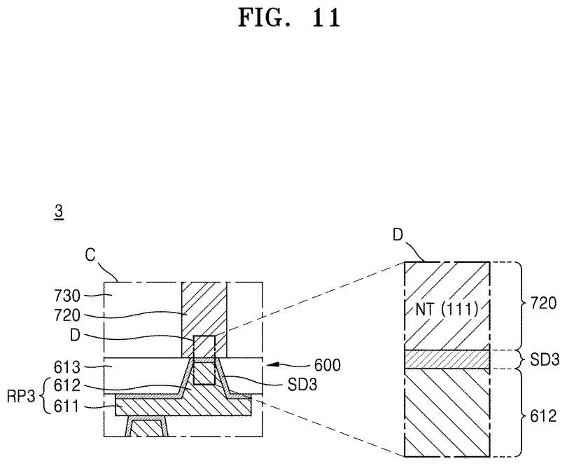

FIG. 10 is a cross-sectional view illustrating a semiconductor package 3 according to one or more embodiments. FIG. 11 is an enlarged cross-sectional view of a portion C of the semiconductor package 3 of FIG. 10.

Referring to FIG. 10 and FIG. 11, the semiconductor package 3 according to embodiments may include a semiconductor chip stack, a lower redistribution structure 600, and a sealing member 730. The semiconductor chip stack may include a plurality of semiconductor chips 710, and among the plurality of semiconductor chips 710, the semiconductor chip 710 which is closest to the lower redistribution structure 600 may be referred to as a lowermost semiconductor chip 710B, and the semiconductor chip 710 which is farthest from the lower redistribution structure 600 may be referred to as an uppermost semiconductor chip 710T.

The plurality of semiconductor chips 710 forming the semiconductor chip stack may be stacked in a stepwise manner. That is, the semiconductor chip stack may be the plurality of semiconductor chips 710 that are sequentially stacked while being offset in a horizontal direction. The plurality of semiconductor chips 710 may be horizontally arranged in an offset direction. In one or more examples, the offset direction is defined as a direction in which one semiconductor chip is shifted with respect to another semiconductor chip under the semiconductor chip when semiconductor chips are stacked. For example, the plurality of semiconductor chips 710 may be arranged in the offset direction in a first direction (the X direction).

The semiconductor chip 710 may include an active surface 711A which is adjacent to a front surface 710F of the semiconductor chip 710 that is a surface facing the lower redistribution structure 600 of the semiconductor chip 710, and a back surface 711B of the semiconductor chip 710 which is opposite to the active surface 711A. The back surface 711B of the semiconductor chip 710 may be referred to as an inactive surface. In some embodiments, a face down arrangement is provided in which the active surface 710A on which components of the semiconductor chip 710 are arranged faces the lower redistribution structure 600, and the semiconductor chip stack may be mounted on the lower redistribution structure 600.

A semiconductor substrate 711 may include, for example, silicon (Si). In one or more examples, the semiconductor substrate 711 may include a semiconductor element, such as germanium (Ge), or a compound semiconductor, such as silicon carbide (SiC), gallium arsenide (GaAs), indium arsenide (InAs), or indium phosphide (InP).

The semiconductor chip 710 may include, for example, a DRAM) chip, an SRAM chip, a flash memory chip, an EEPROM chip, a PRAM chip, an MRAM chip, an RRAM chip, or any other memory structure known to one of ordinary skill in the art.

An adhesive layer 713 may be provided on the back surface 711B of each of the plurality of semiconductor chips 710. The adhesive layer 713 may cover all or at least a part of the back surface 711B of the semiconductor chip 710 to which the adhesive layer 713 is attached. The adhesive layer 713 provided on the back surface 711B of each of the plurality of semiconductor chips 710 excluding the uppermost semiconductor chip 710T may be between the semiconductor chip 710 and another semiconductor chip 710 stacked on the semiconductor chip 710. The adhesive layer 713 may include a die attach film (DAF).

A plurality of chip pads 712 may be provided on the front surface 710F of the semiconductor chip 710. The plurality of chip pads 712 may be electrically connected to other components, such as an integrated circuit, in the semiconductor chip 710. Memory elements and multiple wiring layers may be formed in a lower surface of the semiconductor substrate 711, that is, in the active surface 711A, and the plurality of chip pads 712 may be electrically connected to an integrated circuit in the semiconductor chip 710 through the multiple wiring layers.

A sealing member 730 may surround at least a part of a surface of the semiconductor chip stack. Also, the sealing member 730 may surround side surfaces of the plurality of conductive posts 720 and may be in contact with an upper surface of the lower redistribution structure 600. A side surface of the sealing member 730 may be aligned vertically with a side surface of the lower redistribution structure 600. An upper surface of the sealing member 730 may have the same vertical level as an upper surface of the uppermost semiconductor chip 710T or the adhesive layer 713 provided on the upper surface of the uppermost semiconductor chip 710T. The sealing member 730 may be formed of, for example, (EMC or a polymer material.

In one or more examples, the other semiconductor chips 710, excluding the lowest semiconductor chip 710B among the plurality of semiconductor chips 710, are offset in the horizontal direction. Accordingly, a part of the front surface 710F of the semiconductor chip 710 that is laterally offset from the semiconductor chip 710 located directly under each of the plurality of semiconductor chips 710 may be in contact with the sealing member 730. The plurality of chip pads 712 may be provided on the front surface 710F of the semiconductor chip 710 that is laterally offset from the semiconductor chip 710 located directly thereunder. For example, a plurality of lower redistribution patterns RP3 may be provided to correspond to a vertical downward direction of each of the plurality of chip pads 712.

The lower redistribution structure 600 may be provided at a lower portion of the semiconductor chip stack. The lower redistribution structure 600 may be provided at a lower portion of the lowest semiconductor chip 710B. According to embodiments, the lower redistribution structure 600 may be separated from the lowermost semiconductor chip 710B, and the sealing member 730 may be provided between the lower redistribution structure 600 and the lowermost semiconductor chip 710B.

Side surfaces of the plurality of conductive posts 720 may be surrounded by the sealing member 730, and one end of each of the plurality of conductive posts 720 may be coplanar with one surface of the sealing member 730. That is, a vertical level of one end of each of the plurality of conductive posts 720 may be equal to a vertical level of one surface of the sealing member 730.

The lower redistribution structure 600 may include a plurality of lower redistribution insulating layers 613, and a plurality of lower redistribution patterns RP3 respectively provided in the plurality of lower redistribution insulating layers 613. The plurality of lower redistribution patterns RP3 may respectively include a plurality of lower redistribution line patterns 611, each being arranged on at least a part of an upper or lower surface of each of the plurality of lower redistribution insulating layers 613, and a plurality of lower redistribution via patterns 612, each passing through at least one layer of the plurality of lower redistribution insulating layers 613 and being in contact with a part of each of the plurality of lower redistribution line patterns 611.

The plurality of lower redistribution insulating layers 613 may each be formed of a material film composed of, for example, an organic compound. The plurality of lower redistribution line patterns 611 and the plurality of lower redistribution via patterns 612 may each be a metal, such as copper (Cu), tungsten (W), titanium (Ti), titanium tungsten (TiW), titanium nitride (TiN), tantalum (Ta), tantalum nitride (TaN), chromium (Cr), aluminum (Al), indium (In), molybdenum (Mo), manganese (Mn), cobalt (Co), tin (Sn), nickel (Ni), magnesium (Mg), rhenium (Re), beryllium (Be), gallium (Ga), or ruthenium (Ru), or an alloy thereof, or a metal nitride but is not limited thereto.

The plurality of lower redistribution via patterns 612 may pass through the lower redistribution insulating layer 613 that is in contact with the sealing member 730 among the plurality of lower redistribution insulating layers 613. The plurality of conductive posts 720 may respectively correspond to upper portions of the plurality of lower redistribution via patterns 612. A third seed layer SD3 may be provided between the plurality of lower redistribution via patterns 612 and the plurality of conductive posts 720 respectively corresponding to the plurality of lower redistribution via patterns 612. The third seed layer SD3 may be provided along an upper surface of the lower redistribution pattern RP3 provided on the lower redistribution insulating layer 613 in contact with the sealing member 730. Therefore, the third seed layer SD3 may be in contact with a corresponding conductive post 720 and may be in contact with an upper surface of a corresponding lower redistribution pattern RP3.

The lower redistribution structure 600 may include the plurality of stacked lower redistribution insulating layers 613. The plurality of stacked lower redistribution insulating layer 613 may each be formed of, for example, a photo imageable dielectric (PID) or a photosensitive polyimide (PSPI).

A passivation layer may be provided on a lower surface of the lower redistribution structure 600. The passivation layer, which protects the lower redistribution structure 600, may be formed of a polymer and may cover at least a part of a side surface and lower surface of each of a plurality of external connection pads 614.

A plurality of lower redistribution patterns RP3 may include a plurality of lower redistribution line patterns 611 and a plurality of lower redistribution via patterns 612. The plurality of lower redistribution patterns RP3 may each be a metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), or ruthenium (Ru) or an alloy thereof but is not limited thereto.

Each of the plurality of lower redistribution via patterns 612 may pass through each of the plurality of stacked lower redistribution insulating layer 613 to be connected to a part of each of the plurality of lower redistribution line patterns 611. In some embodiments, the plurality of lower redistribution via patterns 612 may have a tapered shape of which horizontal width is elongated to increase the farther away from the sealing member 730.

Some of the plurality of lower redistribution patterns RP3, which are arranged to be adjacent to a lower surface of the lower redistribution structure 600 may be referred to as the plurality of external connection pads 614. In one or more examples, the plurality of external connection pads 614 may be some of the plurality of lower redistribution line patterns 611 arranged to be adjacent to the lower surface of the lower redistribution structure 600.

The plurality of external connection pads 614 may be respectively connected to a plurality of external connection terminals 615. The semiconductor package 3 may be connected to an external device through the plurality of external connection terminals 615. In some embodiments, the plurality of external connection terminals 615 may be solder bumps or solder balls.

FIG. 11 illustrates a portion C of the semiconductor package 3 on the left and illustrates, on the right of the portion C, an enlarged portion D which is a partial region including the conductive post 720, the third seed layer SD3, and the lower redistribution via pattern 612. The conductive post 720 of the semiconductor package 3 may be formed of copper having a nano-twinned (NT) structure with a (111) orientation. For example, the copper having a nano-twinned structure with a (111) orientation which forms the conductive post 720 may be formed through electroplating. For example, the copper having a nano-twinned structure with a (111) orientation, which is formed through electroplating, may be formed by adjusting the type of copper salt, the electric density applied during a plating process, and so on.

In one or more examples, in the semiconductor package 3 according to one or more embodiments, at least one of the third seed layer SD3 and the lower redistribution patterns RP3 may be formed of copper having a nano-twinned structure with a (111) orientation. The third seed layer SD3 may be formed of the copper having a nano-twinned structure with a (111) orientation through PVD, and the lower redistribution patterns RP3 may be formed of the copper having a nano-twinned structure with a (111) orientation through electroplating.

In a general semiconductor package, a plurality of conductive posts corresponding to a plurality of semiconductor chips may be formed on a plurality of stacked semiconductor chips. As the plurality of conductive posts are formed on the plurality of stacked semiconductor chips, there is a possibility that some of the plurality of conductive posts may have damage, such as collapsing or bending, during a subsequent process of forming a plurality of semiconductor chips and a sealing member surrounding a plurality of conductive posts.

In the semiconductor package 3 according to one or more embodiments, the plurality of conductive posts 720 may be formed of copper having a nano-twinned structure with a (111) orientation and with superior mechanical properties, and accordingly, a possibility that the plurality of conductive posts 720 are damaged may be reduced. Therefore, the possibility of defects occurring during a process of manufacturing the semiconductor package 3 is reduced, and thus, a manufacturing yield of the semiconductor package 3 may be increased.

As described above, embodiments are described with reference to the attached drawings, and those skilled in the art to which the inventive concept belongs will understand that the inventive concept may be modified into other specific forms without changing the technical idea or essential features. Therefore, the embodiments described above are illustrative in all respects and should not be understood as limiting.

While the inventive concept has been particularly shown and described with reference to embodiments thereof, it will be understood that various changes in form and details may be made therein without departing from the spirit and scope of the following claims.

What is claimed is:

1. A semiconductor package comprising:
a first redistribution structure comprising a plurality of redistribution patterns and a plurality of redistribution insulating layers surrounding the plurality of redistribution patterns;
a plurality of conductive posts on the first redistribution structure; and
a sealing member on the first redistribution structure and surrounding the plurality of conductive posts,
wherein the plurality of redistribution insulating layers comprise a first redistribution insulating layer that is closer to the sealing member than other redistribution insulating layers from the plurality of redistribution insulating layers,
wherein the plurality of redistribution patterns comprise a first redistribution pattern in the first redistribution insulating layer,
wherein an end of each of the plurality of conductive posts is in contact with a part of the first redistribution pattern, and a first seed layer is between each of the plurality of conductive posts and the first redistribution pattern, and
wherein each of the plurality of conductive posts has a nano-twinned copper structure with a (111) orientation.

2. The semiconductor package of claim 1, wherein the nano-twinned copper structure constituting the plurality of conductive posts has an average nano-twinned thickness of about 8 nm to about 35 nm.

3. The semiconductor package of claim 1, wherein the first seed layer has the nano-twinned copper structure with the (111) orientation.

4. The semiconductor package of claim 1, wherein each of the first seed layer and the first redistribution pattern has the nano-twinned copper structure with the (111) orientation.

5. The semiconductor package of claim 1, further comprising:
a second seed layer on a side of the first redistribution pattern that is opposite to a side of the first redistribution pattern that the first seed layer is located,
wherein each of the first seed layer, the second seed layer, and the first redistribution pattern has the nano-twinned copper structure with the (111) orientation.

6. The semiconductor package of claim 1, wherein a content of nano-twinned copper with an orientation included in each of the plurality of conductive posts is about 90% to about 99.9%.

7. The semiconductor package of claim 1, wherein an aspect ratio of each of the plurality of conductive posts is about 1 to about 30.

8. The semiconductor package of claim 1, further comprising:
a second redistribution structure on an opposite side of the first redistribution structure based on the plurality of conductive posts and electrically connected to the plurality of conductive posts,
wherein the second redistribution structure includes a plurality of redistribution insulating layers and a plurality of redistribution patterns, and
each of the plurality of redistribution patterns of the second redistribution structure comprises nano-twinned copper having content of 10% or less or comprises non-twinned copper.

9. The semiconductor package of claim 1, wherein
the first redistribution pattern comprises a plurality of first redistribution line patterns and a plurality of first redistribution via patterns,
the plurality of first redistribution line patterns are on the first redistribution insulating layer, the plurality of first redistribution via patterns are in the first redistribution insulating layer, and the plurality of first redistribution via patterns corresponding to the plurality of first redistribution line patterns are formed integrally with the redistribution insulating layer,
the first seed layer is on the plurality of first redistribution line patterns, and
the plurality of conductive posts are on the first seed layer.

10. The semiconductor package of claim 9, wherein each of the plurality of first redistribution via patterns has a tapered shape of which a width of a respective redistribution via pattern decreases the farther away from the plurality of conductive posts.

11. The semiconductor package of claim 1, wherein
the first redistribution pattern comprises a plurality of first redistribution line patterns and a plurality of first redistribution via patterns,
the plurality of first redistribution line patterns are between the plurality of redistribution insulating layers,
the plurality of first redistribution via patterns extend from the plurality of first redistribution line patterns corresponding to the plurality of first redistribution via patterns and are surrounded by the first redistribution insulating layer.

12. The semiconductor package of claim 11, wherein each of the plurality of first redistribution via patterns has a tapered shape of which a width of a first redistribution via pattern increases the farther away from each of the plurality of conductive posts.

13. The semiconductor package of claim 11, wherein the first seed layer is between the plurality of conductive posts and the plurality of first redistribution via patterns, and one surface of the first seed layer is coplanar with one surface of the first redistribution insulating layer.

14. A semiconductor package comprising:
a first redistribution structure comprising a plurality of redistribution patterns and a plurality of redistribution insulating layers;
a plurality of conductive posts provided on the first redistribution structure;
a sealing member provided on the first redistribution structure and surrounding the plurality of conductive posts; and
a second redistribution structure on the sealing member, the second redistribution structure electrically connected to the plurality of conductive posts, and comprising a plurality of redistribution patterns and a plurality of redistribution insulating layers,
wherein the plurality of redistribution insulating layers of the first redistribution structure comprise a first redistribution insulating layer in contact with the sealing member, and the plurality of redistribution patterns of the first redistribution structure comprise a first redistribution pattern,
wherein the first redistribution pattern comprises a first redistribution line pattern and a first redistribution via pattern,
wherein the first redistribution line pattern is on the first redistribution insulating layer, the first redistribution via pattern passes through the first redistribution insulating layer, and the first redistribution line pattern and a corresponding first redistribution via pattern are formed integrally,
each of the plurality of conductive posts comprises a nano-twinned copper structure with a (111) orientation,
a first seed layer is between one end of each of the plurality of conductive posts and the first redistribution pattern, and a second seed layer is provided on one surface of the first redistribution pattern which is an opposite surface of the first seed layer with respect to the first redistribution pattern, and
at least one of the first seed layer, the first redistribution pattern, and the second seed layer comprises a nano-twinned copper structure with a (111) orientation.

15. The semiconductor package of claim 14, wherein the nano-twinned copper structure has an average nano-twinned thickness of about 8 nm to about 35 nm.

16. The semiconductor package of claim 14, wherein a content of nano-twinned copper with the (111) orientation in each of the plurality of conductive posts is determined to be 90% or more.

17. The semiconductor package of claim 14, wherein
a first semiconductor device is on the second redistribution structure,
a second semiconductor device laterally separated from the first semiconductor device is on the second redistribution structure,
the first semiconductor device comprises a logic chip, and
the second semiconductor device comprises a memory chip.

18. A semiconductor package comprising:
a redistribution structure comprising a plurality of redistribution patterns and a plurality of redistribution insulating layers surrounding the plurality of redistribution patterns;
a plurality of conductive posts on the redistribution structure; and
a sealing member on the redistribution structure and surrounding the plurality of conductive posts,
wherein the plurality of redistribution insulating layers comprise a first redistribution insulating layer that is closer to the sealing member than other redistribution layers form the plurality of redistribution layers, and the plurality of redistribution patterns include a first redistribution pattern provided in the first redistribution insulating layer,
wherein an end of each of the plurality of conductive posts is in contact with a part of the first redistribution pattern, and a first seed layer is between each of the plurality of conductive posts and the first redistribution pattern,
wherein each of the plurality of conductive posts comprises copper, and
wherein an average size of copper grains included in the plurality of conductive posts is about 0.1 μm to about 0.8 μm.

19. The semiconductor package of claim 18, wherein the first seed layer is provided between an end of each of the plurality of conductive posts and the first redistribution pattern, and an average size of copper grains included in the first seed layer is about 0.1 μm to about 0.8 μm.

20. The semiconductor package of claim 19, wherein
a second seed layer is provided on one surface of the first redistribution pattern which is an opposite surface of the first seed layer with respect to the first redistribution pattern, and
an average size of copper grains included in at least one of the first redistribution pattern and the second seed layer is about 0.1 μm to about 0.8 μm.
